(19) United States
(12) Patent Application Publication
(10) Pub. No.: US 2022/0173298 A1
(43) Pub. Date: Jun. 2, 2022

(54) THERMOELECTRIC MODULE AND OPTICAL MODULE

(71) Applicant: KELK Ltd., Kanagawa (JP)

(72) Inventors: Tetsushi TANAKA, Kanagawa (JP); Katsushi FUKUDA, Kanagawa (JP); Akio KONISHI, Kanagawa (JP); Hiroyuki MATSUNAMI, Kanagawa (JP); Takaaki OHTA, Kanagawa (JP); Haruka KOREEDA, Kanagawa (JP)

(21) Appl. No.: 17/437,167

(22) PCT Filed: Mar. 16, 2020
(86) PCT No.: PCT/JP2020/011573

§ 371 Date: Sep. 8, 2021

(30) Foreign Application Priority Data
Mar. 19, 2019 (JP) 2019-051808

(51) Int. Cl. H01L 35/08; H01S 5/024; H01L 35/30; H01L 35/32; H01L 35/34

(52) U.S. Cl. CPC H01L 35/08; H01S 5/02415; H01L 35/34; H01L 35/32; H01L 35/30

(57) ABSTRACT

A thermoelectric module includes a substrate, an electrode provided on a first surface of the substrate, a thermoelectric element, and a first diffusion prevention layer disposed between the electrode and the thermoelectric element. The first diffusion prevention layer includes a first material having a lower ionization tendency than that of hydrogen.

### FIELD

The present invention relates to a thermoelectric module and an optical module.

### BACKGROUND

Thermoelectric modules that absorb heat or generate heat by the Peltier effect are known. When a thermoelectric element of a thermoelectric module is energized, the thermoelectric module absorbs heat or generates heat.

### CITATION LIST

### Patent Literature

Patent Literature 1: JP 2016-111326 A

### SUMMARY

### Technical Problem

When a thermoelectric module is energized in a dew condensation state, electrochemical migration occurs, and there is a possibility that an electrical short circuit or disconnection occurs due to migration of a metal used as an electrode or a diffusion prevention layer.

An aspect of the present invention is to provide a thermoelectric module capable of suppressing occurrence of electrical short circuit or disconnection.

### Solution to Problem

According to an aspect of the present invention, a thermoelectric module comprises: a substrate; an electrode provided on a first surface of the substrate; a thermoelectric element; and a first diffusion prevention layer disposed between the electrode and the thermoelectric element, wherein the first diffusion prevention layer includes a first material having a lower ionization tendency than an ionization tendency of hydrogen.

### Advantageous Effects of Invention

An aspect of the present invention provides a thermoelectric module capable of suppressing occurrence of electrical short circuit or disconnection.

### BRIEF DESCRIPTION OF DRAWINGS

FIG. 1 is a cross-sectional view illustrating an optical module according to a first embodiment.

FIG. 2 is a sectional view illustrating a thermoelectric module according to the first embodiment.

FIG. 3 is an enlarged sectional view illustrating a part of the thermoelectric module according to the first embodiment.

FIG. 4 is a flowchart illustrating a method for manufacturing the thermoelectric module according to the first embodiment.

FIG. 5 is a sectional view illustrating a thermoelectric module according to a second embodiment.

FIG. 6 is an enlarged sectional view illustrating a part of the thermoelectric module according to the second embodiment.

FIG. 7 is a flowchart illustrating a method for manufacturing the thermoelectric module according to the second embodiment.

FIG. 8 is an enlarged sectional view illustrating a part of the thermoelectric module according to the second embodiment.

### DESCRIPTION OF EMBODIMENTS

Hereinafter, embodiments according to the present invention will be described with reference to the drawings. However, the present invention is not limited thereto. Components of a plurality of embodiments described below can be appropriately combined. In addition, some components may not be used.

In the following description, an XYZ orthogonal coordinate system is set, and a positional relationship of each part will be described with reference to the XYZ orthogonal coordinate system. A direction parallel to an X axis in a predetermined plane is defined as an X axis direction, a direction parallel to a Y axis orthogonal to the X axis in the predetermined plane is defined as a Y axis direction, and a direction parallel to a Z axis orthogonal to the predetermined plane is defined as a Z axis direction. The X axis, the Y axis, and the Z axis are orthogonal to each other. Still more, a plane including the X axis and the Y axis is defined as an XY plane, a plane including the Y axis and the Z axis is defined as an YZ plane, and a plane including the Z axis and the X axis is defined as an XZ plane. The XY plane is parallel to the predetermined plane. The XY plane, the YZ plane, and the XZ plane are orthogonal to each other.

### First Embodiment

<Optical Module>

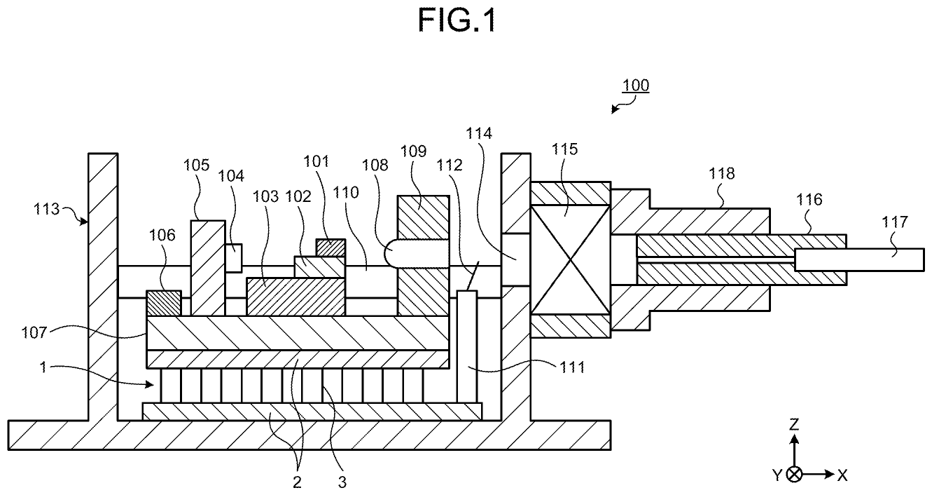

FIG. 1 is a cross-sectional view illustrating an optical module 100 according to the present embodiment. The optical module 100 is used for, for example, optical communication. As illustrated in FIG. 1, the optical module 100 includes a thermoelectric module 1, a light-emitting element 101, a heat sink 102, a first header 103, a light-receiving element 104, a second header 105, a temperature sensor 106, a metal plate 107, a lens 108, a lens holder 109, a first terminal 110, a second terminal 111, a wire 112, and a housing 113.

In addition, the optical module 100 includes an optical isolator 115, an optical ferrule 116, an optical fiber 117, and a sleeve 118.

The thermoelectric module 1 absorbs heat or generates heat by the Peltier effect. The thermoelectric module 1 includes a pair of substrates 2 and a thermoelectric element 3 disposed between the pair of substrates 2.

The light-emitting element 101 emits light. The light-emitting element 101 includes, for example, a laser diode that emits laser light. The heat sink 102 supports the light-emitting element 101. The heat sink 102 dissipates a heat generated by the light-emitting element 101. The first header 103 supports the heat sink 102. The heat sink 102 is fixed to the first header 103.

The light-receiving element 104 detects light generated from the light-emitting element 101. The light-receiving element 104 includes, for example, a photodiode. The second header 105 supports the light-receiving element 104. The light-receiving element 104 is fixed to the second header 105.

The temperature sensor 106 detects a temperature of the metal plate 107. The temperature sensor 106 includes, for example, a thermistor.

The metal plate 107 supports the first header 103, the second header 105, and the temperature sensor 106. The first header 103, the second header 105, and the temperature sensor 106 are fixed to the metal plate 107 by soldering.

The lens 108 collects the light emitted from the light-emitting element 101. The lens holder 109 holds the lens 108.

The first terminal 110 is connected to the first header 103, the second header 105, and the temperature sensor 106. The second terminal 111 is connected to the thermoelectric module 1. The first terminal 110 and the second terminal 111 are connected via the wire 112.

The housing 113 accommodates the thermoelectric module 1, the light-emitting element 101, the heat sink 102, the first header 103, the light-receiving element 104, the second header 105, the temperature sensor 106, the metal plate 107, the lens 108, the lens holder 109, the first terminal 110, the second terminal 111, and the wire 112. The housing 113 has an opening 114 through which the light emitted from the light-emitting element 101 passes.

The optical isolator 115 is disposed outside the housing 113 so as to close the opening 114. The optical isolator 115 allows light traveling in one direction to pass therethrough and blocks light traveling in the opposite direction. The light emitted from the light-emitting element 101 and passing through the lens 108 enters the optical isolator 115 through the opening 114. The light incident on the optical isolator 115 passes through the optical isolator 115.

The optical ferrule 116 guides the light emitted from the optical isolator 115 to the optical fiber 117. The sleeve 118 supports the optical ferrule 116.

Next, the operation of the optical module 100 will be described. The light emitted from the light-emitting element 101 is collected by the lens 108 and then enters the optical isolator 115 through the opening 114. The light incident on the optical isolator 115 passes through the optical isolator 115 and then enters an end face of the optical fiber 117 via the optical ferrule 116.

At least a part of the light generated from the light-emitting element 101 is emitted toward the light-receiving element 104. The light-receiving element 104 receives the light emitted from the light-emitting element 101. The light-receiving element 104 monitors a light-emitting state of the light-emitting element 101.

The heat generated from the light-emitting element 101 is transmitted to the metal plate 107 via the heat sink 102 and the first header 103. The temperature sensor 106 detects a temperature of the metal plate 107. When the temperature sensor 106 detects that the temperature of the metal plate 107 reaches a specified temperature, a current is supplied to the thermoelectric module 1. When the thermoelectric element 3 of the thermoelectric module 1 is energized, the thermoelectric module 1 absorbs heat by the Peltier effect. Thus, the light-emitting element 101 is cooled. The temperature of the light-emitting element 101 is adjusted by the thermoelectric module 1.

<Thermoelectric Module>

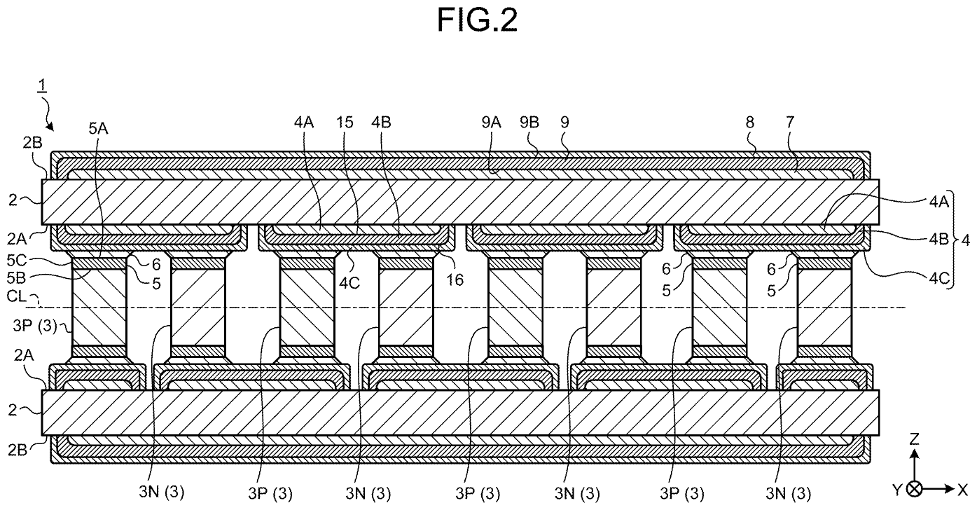

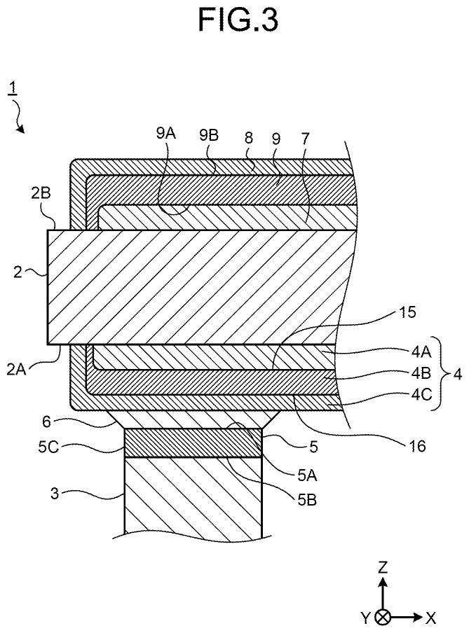

FIG. 2 is a sectional view illustrating the thermoelectric module 1 according to the present embodiment. FIG. 3 is an enlarged sectional view illustrating a part of the thermoelectric module 1 according to the present embodiment.

The thermoelectric module 1 includes a pair of substrates 2 and a thermoelectric element 3 disposed between the pair of substrates 2.

The substrates 2 are formed of an electrically insulating material. In the present embodiment, the substrates 2 are ceramic substrates. The substrates 2 are formed of oxide ceramic or nitride ceramic. Examples of the oxide ceramic are aluminum oxide (Al₂O₃) and zirconium oxide (ZrO₂). Examples of the nitride ceramic are silicon nitride (Si₃N₄) and aluminum nitride (AlN).

The thermoelectric element 3 is made of a thermoelectric material such as a bismuth tellurium compound (Bi—Te). The thermoelectric element 3 includes a first thermoelectric element 3N that is an n-type thermoelectric semiconductor element, and a second thermoelectric element 3P that is a p-type thermoelectric semiconductor element. A plurality of first thermoelectric elements 3N and a plurality of second thermoelectric elements 3P are disposed on the XY plane. The first thermoelectric elements 3N and the second thermoelectric elements 3P are alternately arranged in the X-axis direction. The first thermoelectric elements 3N and the second thermoelectric elements 3P are alternately arranged in the Y-axis direction.

Examples of the thermoelectric material forming the thermoelectric element 3 are bismuth (Bi), a bismuth tellurium compound (Bi—Te), a bismuth antimony compound (Bi—Sb), a lead tellurium compound (Pb—Te), a cobalt antimony compound (Co—Sb), an iridium antimony compound (Ir—Sb), a cobalt arsenic compound (Co—As), a silicon germanium compound (Si—Ge), a copper selenium compound (Cu—Se), a gadolinium selenium compound (Gd—Se), a boron carbide compound, a tellurium perovskite oxide, a rare earth sulfide, a TAGS compound (GeTe—AgSbTe₂), Heusler type TiNiSn, FeNbSb, and a TiCoSb substance.

The thermoelectric module 1 has a substantially symmetrical structure in the Z-axis direction. In the following description, a structure on the +Z side of a symmetry line CL in FIG. 2 will be mainly described.

The substrate 2 has a first surface 2A and a second surface 2B. The first surface 2A faces a space between the pair of substrates 2. In other words, the first surface 2A faces the space where the thermoelectric element 3 exists. The second surface 2B faces a direction opposite to the first surface 2A. Each of the first surface 2A and the second surface 2B is substantially parallel to the XY plane.

The thermoelectric module 1 includes an electrode 4 provided on the first surface 2A of the substrate 2, a first diffusion prevention layer 5 disposed between the electrode 4 and the thermoelectric element 3, and a bonding layer 6 provided between the electrode 4 and the first diffusion prevention layer 5.

The thermoelectric module 1 includes, on the second surface 2B of the substrate 2, a first metal layer 7, a second metal layer 8, and a second diffusion prevention layer 9 disposed between the first metal layer 7 and the second metal layer 8.

The electrode 4 provides power to the thermoelectric element 3. The electrode 4 includes a first electrode layer 4A in contact with the first surface 2A, a second electrode layer 4B covering the first electrode layer 4A, and a third electrode layer 4C covering the second electrode layer 4B.

A plurality of electrodes 4 are provided on the first surface 2A. Each of the electrodes 4 is connected to each of an adjacent pair of the first thermoelectric elements 3N and the second thermoelectric elements 3P. The electrode 4 is connected to the thermoelectric element 3 via the bonding layer 6 and the first diffusion prevention layer 5.

The first electrode layer 4A is formed of copper (Cu). The second electrode layer 4B is formed of a material having a lower ionization tendency than that of hydrogen. As a material for forming the second electrode layer 4B, at least one of palladium (Pd), platinum (Pt), gold (Au), and rhodium (Rh) is exemplified. In the present embodiment, the second electrode layer 4B is formed of palladium (Pd). The third electrode layer 4C is formed of gold (Au).

The bonding layer 6 bonds the electrode 4 and the first diffusion prevention layer 5. An example of a material for forming the bonding layer 6 is lead-free solder containing tin (Sn) as a main component. Lead-free solder refers to solder having a lead content of 0.10 mass % or less. Examples of a solder material for forming the bonding layer 6 are tin-antimony alloy-based (Sn—Sb-based) solder that is an intermetallic compound of tin (Sn) and antimony (Sb), gold-tin alloy-based (Au—Sn-based) solder that is an intermetallic compound of gold (Au) and tin (Sn), and copper-tin alloy-based (Cu—Sn-based) solder that is an intermetallic compound of copper (Cu) and tin (Sn).

In other words, in the present embodiment, the electrode 4 and the first diffusion prevention layer 5 are bonded by soldering. The first diffusion prevention layer 5 is connected to the electrode 4 via the bonding layer 6. The first diffusion prevention layer 5 is in contact with the bonding layer 6. The electrode 4 is in contact with the bonding layer 6. In the present embodiment, the third electrode layer 4C of the electrode 4 is in contact with the bonding layer 6.

The first diffusion prevention layer 5 suppresses diffusion of elements contained in the bonding layer 6 into the thermoelectric element 3. Diffusion of elements contained in the bonding layer 6 into the thermoelectric element 3 is suppressed, so that deterioration in performance of the thermoelectric element 3 is suppressed.

The first diffusion prevention layer 5 is formed of a material (first material) having a lower ionization tendency than hydrogen. As a material for forming the first diffusion prevention layer 5, at least one of palladium (Pd), platinum (Pt), gold (Au), and rhodium (Rh) is exemplified. In the present embodiment, the first diffusion prevention layer 5 is formed of palladium (Pd).

The first diffusion prevention layer 5 is in contact with each of the bonding layer 6 and the thermoelectric element 3. The first diffusion prevention layer 5 has a first contact surface 5A in contact with the bonding layer 6, a second contact surface 5B in contact with the thermoelectric element 3, and a side surface 5C connecting a peripheral portion of the first contact surface 5A and a peripheral portion of the second contact surface 5B. Each of the first contact surface 5A, the second contact surface 5B, and the side surface 5C is formed of a material having a lower ionization tendency than hydrogen. In the present embodiment, the first diffusion prevention layer 5 is formed only of a material having a lower ionization tendency than hydrogen.

The third electrode layer 4C is bonded to the first diffusion prevention layer 5 by the bonding layer 6 that is solder. The third electrode layer 4C is formed of gold (Au) that can be easily bonded to the first diffusion prevention layer 5 by soldering. The second electrode layer 4B functions as a diffusion prevention layer that suppresses diffusion of elements contained in the first electrode layer 4A into the third electrode layer 4C. The second electrode layer 4B is provided so as to cover the first electrode layer 4A. Diffusion of elements contained in the first electrode layer 4A into the third electrode layer 4C is suppressed, so that the third electrode layer 4C and the first diffusion prevention layer 5 are sufficiently connected via the bonding layer 6.

The first metal layer 7 is in contact with the second surface 2B of the substrate 2. The first metal layer 7 is formed of a metal having high thermal conductivity. In the present embodiment, the first metal layer 7 is formed of copper (Cu). By using copper (Cu) having high thermal conductivity as the first metal layer 7, a temperature of the first metal layer 7 is made uniform when each of the plurality of thermoelectric elements 3 absorbs heat or generates heat.

The second metal layer 8 is connected to a temperature target of the thermoelectric module 1. The second metal layer 8 is provided so as to cover the second diffusion prevention layer 9. In the present embodiment, the second metal layer 8 is connected to the metal plate 107 described with reference to FIG. 1. The second metal layer 8 and the metal plate 107 are bonded by soldering. The second metal layer 8 is formed of a metal that can be easily bonded to the metal plate 107 by soldering. In the present embodiment, the second metal layer 8 is formed of gold (Au).

The second diffusion prevention layer 9 suppresses diffusion of elements contained in the first metal layer 7 into the second metal layer 8. The second diffusion prevention layer 9 is provided so as to cover the first metal layer 7. Diffusion of elements contained in the first metal layer 7 into the second metal layer 8 is suppressed, so that the second metal layer 8 and the metal plate 107 are sufficiently connected.

The second diffusion prevention layer 9 is formed of a material (third material) having a lower ionization tendency than hydrogen. As a material for forming the second diffusion prevention layer 9, at least one of palladium (Pd), platinum (Pt), gold (Au), and rhodium (Rh) is exemplified. In the present embodiment, the second diffusion prevention layer 9 is formed of palladium (Pd).

In the present embodiment, the material for forming the first diffusion prevention layer 5 and the material for forming the second diffusion prevention layer 9 are the same. However, the material for forming the first diffusion prevention layer 5 and the material for forming the second diffusion prevention layer 9 may be different from each other. For example, the material for forming the first diffusion prevention layer 5 may be palladium (Pd), and the material for forming the second diffusion prevention layer 9 may be platinum (Pt).

The second diffusion prevention layer 9 is in contact with each of the first metal layer 7 and the second metal layer 8. The second diffusion prevention layer 9 has a third contact surface 9A in contact with the first metal layer 7 and a fourth contact surface 9B in contact with the second metal layer 8. Each of the third contact surface 9A and the fourth contact surface 9B is made of a material having a lower ionization tendency than hydrogen. In the present embodiment, the second diffusion prevention layer 9 is formed only of a material having a lower ionization tendency than hydrogen.

The second electrode layer 4B is in contact with each of the first electrode layer 4A and the third electrode layer 4C. The second electrode layer 4B has a fifth contact surface 15 in contact with the first electrode layer 4A and a sixth contact surface 16 in contact with the third electrode layer 4C. Each of the fifth contact surface 15 and the sixth contact surface 16 is made of a material having a lower ionization tendency than hydrogen. In the present embodiment, the second electrode layer 4B is formed only of a material having a lower ionization tendency than hydrogen.

<Method for Manufacturing Thermoelectric Module>

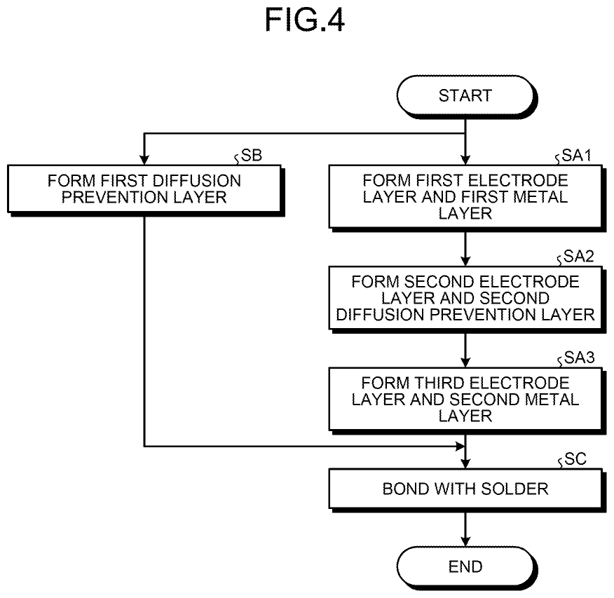

FIG. 4 is a flowchart illustrating a method for manufacturing the thermoelectric module 1 according to the present embodiment. The first electrode layer 4A is formed on the first surface 2A of the substrate 2, and the first metal layer 7 is formed on the second surface 2B of the substrate 2. For example, the first electrode layer 4A and the first metal layer 7 are formed by plating the substrate 2 (Step SA1).

Next, the second electrode layer 4B is formed so as to cover the first electrode layer 4A, and the second diffusion prevention layer 9 is formed so as to cover the first metal layer 7. For example, the second electrode layer 4B and the second diffusion prevention layer 9 are formed by plating (Step SA2).

Next, the third electrode layer 4C is formed so as to cover the second electrode layer 4B, and the second metal layer 8 is formed so as to cover the second diffusion prevention layer 9. For example, the third electrode layer 4C and the second metal layer 8 are formed by plating (Step SA3).

The first diffusion prevention layer 5 is formed on an end surface of the thermoelectric element 3. For example, the first diffusion prevention layer 5 is formed by sputtering (Step SB).

The third electrode layer 4C of the substrate 2 after the process of Step SA3 and the first diffusion prevention layer 5 of the thermoelectric element 3 after the process of Step SB are bonded by soldering (Step SC).

By the process of Step SC, the first diffusion prevention layer 5 is connected to the electrode 4 via the bonding layer 6.

<Effects>

As described above, according to the present embodiment, the first diffusion prevention layer 5 is formed of a material having a lower ionization tendency than hydrogen. Accordingly, occurrence of electrochemical migration is suppressed even when the thermoelectric module 1 is energized in a dew condensation state. Therefore, occurrence of an electrical short circuit or disconnection due to migration of metals used as the electrode or the diffusion prevention layer is suppressed. In addition, deterioration of the thermoelectric element 3 due to electrochemical migration is suppressed. Accordingly, performance of the thermoelectric module 1 is maintained for a long period of time.

The present inventor has found that when the first diffusion prevention layer (5) is formed of a material having a higher ionization tendency than hydrogen, electrochemical migration is highly likely to occur when the thermoelectric module 1 is energized in the dew condensation state. In addition, the present inventor has found that when the first diffusion prevention layer 5 is formed of a material having a lower ionization tendency than hydrogen, occurrence of electrochemical migration is suppressed even when the thermoelectric module 1 is energized in the dew condensation state. An example of a material having a higher ionization tendency than hydrogen is Nickel (Ni).

When a temperature controlled by the thermoelectric module 1 falls below a dew point of the ambient environmental atmosphere, the thermoelectric module 1 is highly likely to cause dew condensation. Therefore, when the first diffusion prevention layer is formed of a material such as nickel (Ni), it is necessary to enhance airtightness of the housing (113) and fill an internal space of the housing with an inert gas in order to prevent occurrence of electrochemical migration. A configuration of enhancing the airtightness of the housing and filling the internal space of the housing with the inert gas increases the cost.

In the present embodiment, the first diffusion prevention layer 5 is formed of a material having a lower ionization tendency than that of hydrogen. Therefore, even when the airtightness of the housing 113 is low, the occurrence of electrochemical migration is suppressed. Accordingly, thermoelectric module 1 and optical module 100 with reduced cost can be provided.

### Second Embodiment

A second embodiment will be described. In the following description, the same or equivalent components as those of the above-described embodiment are denoted by the same reference signs, and the description thereof is simplified or omitted.

The above-described embodiment refers to an example of forming each of the first diffusion prevention layer 5, the second diffusion prevention layer 9, and the second electrode layer 4B only of a material having a lower ionization tendency than that of hydrogen. In the present embodiment, an example will be described in which each of the first diffusion prevention layer 5, the second diffusion prevention layer 9, and the second electrode layer 4B is formed of a material having a higher ionization tendency than that of hydrogen and a material having a lower ionization tendency than that of hydrogen.

<Thermoelectric Module>

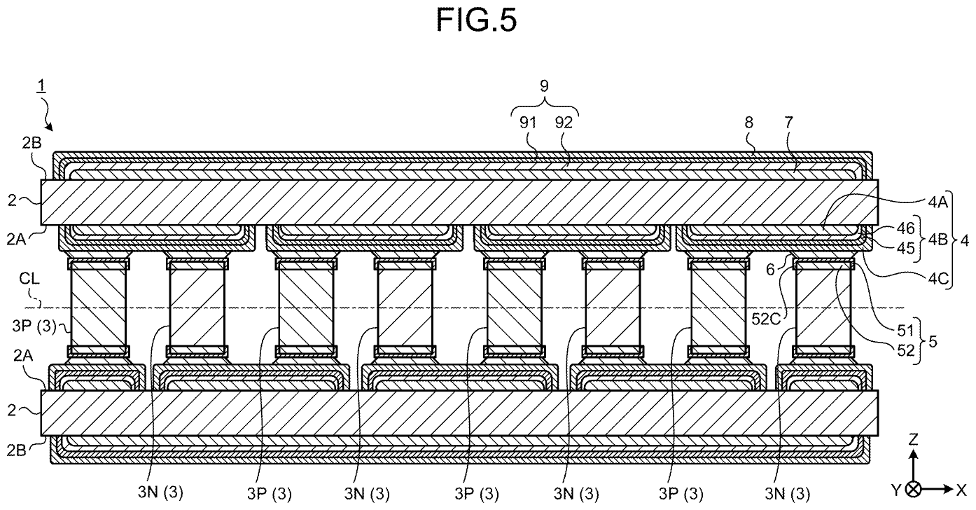

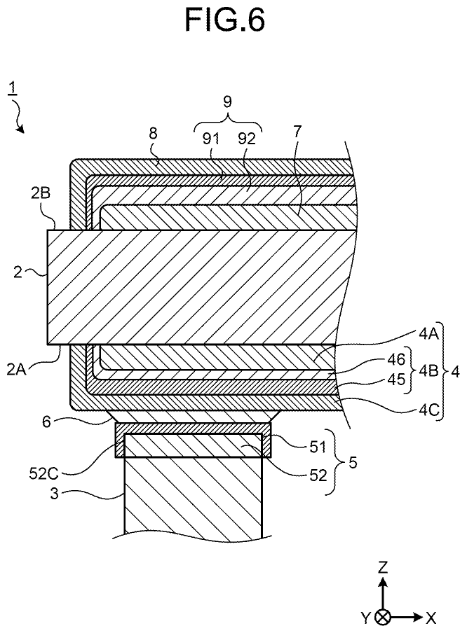

FIG. 5 is a sectional view illustrating a thermoelectric module 1 according to the present embodiment. FIG. 6 is an enlarged sectional view illustrating a part of the thermoelectric module 1 according to the present embodiment.

In the present embodiment, the first diffusion prevention layer 5 includes a second material layer 52 formed of a material (second material) having a higher ionization tendency than that of hydrogen, and a first material layer 51 formed of a material (first material) having a lower ionization tendency than that of hydrogen and covering a side surface 52C of the second material layer 52.

As a material for forming the first material layer 51, at least one of palladium (Pd), platinum (Pt), gold (Au), and rhodium (Rh) is exemplified. As a material for forming the second material layer 52, nickel (Ni) is exemplified.

The first material layer 51 covers at least the side surface 52C of the second material layer 52. The surface of the second material layer 52 is not exposed by the first material layer 51.

The bonding layer 6 is provided between the electrode 4 and the first diffusion prevention layer 5. At least a part of the first material layer 51 is disposed between the bonding layer 6 and the second material layer 52. The first material layer 51 is in contact with the bonding layer 6. The second material layer 52 is in contact with the thermoelectric element 3.

In the present embodiment, the second diffusion prevention layer 9 includes a fourth material layer 92 formed of a material (fourth material) having a higher ionization tendency than that of hydrogen, and a third material layer 91 formed of a material (third material) having a lower ionization tendency than that of hydrogen and disposed between the fourth material layer 92 and the second metal layer 8.

As a material for forming the third material layer 91, at least one of palladium (Pd), platinum (Pt), gold (Au), and rhodium (Rh) is exemplified. As a material for forming the fourth material layer 92, nickel (Ni) is exemplified.

The third material layer 91 is in contact with each of the second metal layer 8 and the fourth material layer 92. The fourth material layer 92 is in contact with the first metal layer 7.

In the present embodiment, the second electrode layer 4B includes a sixth material layer 46 formed of a material having a higher ionization tendency than that of hydrogen, and a fifth material layer 45 formed of a material having a lower ionization tendency than that of hydrogen and disposed between the sixth material layer 46 and the third electrode layer 4C.

As a material for forming the fifth material layer 45, at least one of palladium (Pd), platinum (Pt), gold (Au), and rhodium (Rh) is exemplified. As a material for forming the sixth material layer 46, nickel (Ni) is exemplified.

The fifth material layer 45 is in contact with each of the third electrode layer 4C and the sixth material layer 46. The sixth material layer 46 is in contact with the first electrode layer 4A.

<Method for Manufacturing Thermoelectric Module>

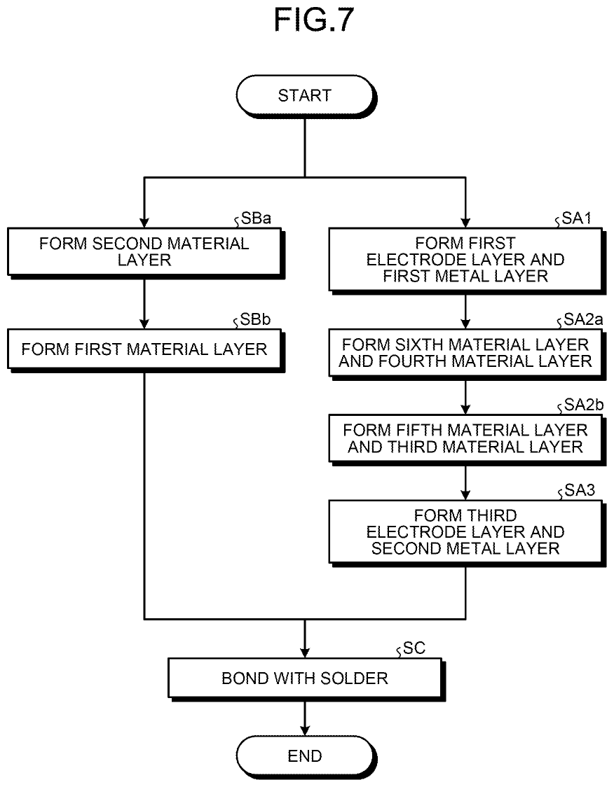

FIG. 7 is a flowchart illustrating a method for manufacturing the thermoelectric module 1 according to the present embodiment. The first electrode layer 4A is formed on the first surface 2A of the substrate 2, and the first metal layer 7 is formed on the second surface 2B of the substrate 2. For example, the first electrode layer 4A and the first metal layer 7 are formed by plating the substrate 2 (Step SA1).

Next, the sixth material layer 46 is formed so as to cover the first electrode layer 4A, and the fourth material layer 92 is formed so as to cover the first metal layer 7. For example, the first metal layer 7 and the fourth material layer 92 are formed by plating (Step SA2a).

Next, the fifth material layer 45 is formed so as to cover the sixth material layer 46, and the third material layer 91 is formed so as to cover the fourth material layer 92. For example, the fifth material layer 45 and the third material layer 91 are formed by plating (Step SA2b).

Next, the third electrode layer 4C is formed so as to cover the fifth material layer 45, and the second metal layer 8 is formed so as to cover the third material layer 91. For example, the third electrode layer 4C and the second metal layer 8 are formed by plating (Step SA3).

The second material layer 52 is formed on the end surface of the thermoelectric element 3. For example, the second material layer 52 is formed by plating (Step SBa).

Next, the first material layer 51 is formed so as to cover the second material layer 52. For example, the first material layer 51 is formed by sputtering (Step SBb).

The third electrode layer 4C of the substrate 2 after the process of Step SA3 and the first material layer 51 of the thermoelectric element 3 after the process of Step SBb are bonded by soldering (Step SC).

By the process of Step SC, the first diffusion prevention layer 5 is connected to the electrode 4 via the bonding layer 6.

<Effects>

As described above, in the present embodiment, the first diffusion prevention layer 5 includes the second material layer 52 formed of the material having a higher ionization tendency than that of hydrogen, such as nickel. The surface (exposed surface) of the second material layer 52 is covered with the first material layer 51 formed of the material having a lower ionization tendency than that of hydrogen. Accordingly, even when the thermoelectric module 1 is dew condensed, moisture is prevented from coming into contact with the second material layer 52. Therefore, even when the thermoelectric element 3 is energized, occurrence of electrochemical migration is suppressed. Thus, occurrence of an electrical short circuit or disconnection due to migration of metals used as the electrode or the diffusion prevention layer is suppressed. In addition, deterioration of the thermoelectric element 3 is suppressed, and performance of the thermoelectric module 1 is maintained for a long period.

### Modified Example

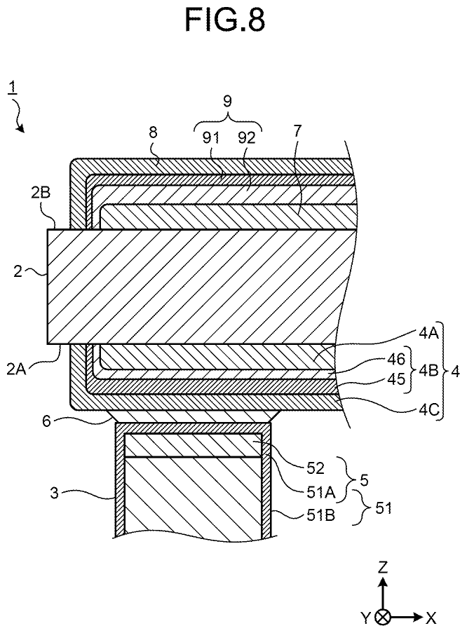

FIG. 8 is an enlarged sectional view illustrating a part of the thermoelectric module 1 according to the present embodiment. As illustrated in FIG. 8, the first material layer 51 may include a first material layer 51A covering the surface of the second material layer 52 and a first material layer 51B covering the surface of the thermoelectric element 3. For example, in Step SBb described above, the first material layer 51A may be formed on the surface of the second material layer 52 provided in the thermoelectric element 3, and the first material layer 51B may be formed on the surface of the thermoelectric element 3 provided with the second material layer 52.

### OTHER EMBODIMENTS

The first diffusion prevention layer 5 may be formed only of a material having a lower ionization tendency than that of hydrogen, and the second diffusion prevention layer 9 may include the third material layer 91 and the fourth material layer 92. The first diffusion prevention layer 5 may include the first material layer 51 and the second material layer 52, and the second diffusion prevention layer 9 may be formed only of a material having a lower ionization tendency than that of hydrogen.

In the above embodiments, the thermoelectric module 1 absorbs heat or generates heat by the Peltier effect. The thermoelectric module 1 may generate electric power by the Seebeck effect. When a temperature difference is given to the pair of substrates 2 of the thermoelectric module 1, the thermoelectric module 1 can generate electric power by the Seebeck effect.

In the above embodiments, the second terminal 111 connected to the thermoelectric module 1 may also be made of the material having a lower ionization tendency than that of hydrogen. In addition, the second terminal 111 may be formed by covering the surface of the material having a higher ionization tendency than that of hydrogen with the material having a lower ionization tendency than that of hydrogen. The connecting portion of the second terminal 111 connected to the wire 112 is formed of a material connectable to the wire 112. For example, a gold film is exemplified as a surface of the connecting portion of the second terminal 111 connectable to the wire 112. Since the surface of the connecting portion of the second terminal 111 is formed of a gold film, the wire 112 can be bonded. When a lead wire is used instead of the wire 112, the lead wire and the connecting portion may also be made of a material having a lower ionization tendency than that of hydrogen.

### REFERENCE SIGNS LIST

1 THERMOELECTRIC MODULE
2 SUBSTRATE
2A FIRST SURFACE
2B SECOND SURFACE
3 THERMOELECTRIC ELEMENT
3N FIRST THERMOELECTRIC ELEMENT
3P SECOND THERMOELECTRIC ELEMENT
4 ELECTRODE
4A FIRST ELECTRODE LAYER
4B SECOND ELECTRODE LAYER
4C THIRD ELECTRODE LAYER
5 FIRST DIFFUSION PREVENTION LAYER
5A FIRST CONTACT SURFACE
5B SECOND CONTACT SURFACE
5C SIDE SURFACE
6 BONDING LAYER
7 FIRST METAL LAYER
8 SECOND METAL LAYER
9 SECOND DIFFUSION PREVENTION LAYER
9A THIRD CONTACT SURFACE
9B FOURTH CONTACT SURFACE
15 FIFTH CONTACT SURFACE
16 SIXTH CONTACT SURFACE
51 FIRST MATERIAL LAYER
51A FIRST MATERIAL LAYER
51B FIRST MATERIAL LAYER
52 SECOND MATERIAL LAYER
52C SIDE SURFACE
45 FIFTH MATERIAL LAYER
46 SIXTH MATERIAL LAYER
91 THIRD MATERIAL LAYER
92 FOURTH MATERIAL LAYER
100 OPTICAL MODULE
101 LIGHT-EMITTING ELEMENT
102 HEAT SINK
103 FIRST HEADER
104 LIGHT-RECEIVING ELEMENT
105 SECOND HEADER
106 TEMPERATURE SENSOR
107 METAL PLATE
108 LENS
109 LENS HOLDER
110 FIRST TERMINAL
111 SECOND TERMINAL
112 WIRE
113 HOUSING
114 OPENING
115 OPTICAL ISOLATOR
116 OPTICAL FERRULE
117 OPTICAL FIBER
118 SLEEVE
CL SYMMETRY LINE

1. A thermoelectric module comprising:
a substrate;
an electrode provided on a first surface of the substrate;
a thermoelectric element; and
a first diffusion prevention layer disposed between the electrode and the thermoelectric element, wherein
the first diffusion prevention layer includes a first material having a lower ionization tendency than an ionization tendency of hydrogen.

2. The thermoelectric module according to claim 1, comprising:
a bonding layer provided between the electrode and the first diffusion prevention layer, wherein
the first diffusion prevention layer has a first contact surface in contact with the bonding layer, a second contact surface in contact with the thermoelectric element, and a side surface, and
each of the first contact surface, the second contact surface, and the side surface is formed of the first material.

3. The thermoelectric module according to claim 1, wherein
the first diffusion prevention layer includes a second material layer formed of a second material having a higher ionization tendency than an ionization tendency of hydrogen, and a first material layer formed of the first material and covering a side surface of the second material layer.

4. The thermoelectric module according to claim 3, comprising:
a bonding layer provided between the electrode and the first diffusion prevention layer, wherein
at least a part of the first material layer is disposed between the bonding layer and the second material layer, and
the second material layer is in contact with the thermoelectric element.

5. The thermoelectric module according to claim 3, wherein the second material includes nickel.

6. The thermoelectric module according to claim 1, wherein the first material includes at least one of palladium, platinum, gold, and rhodium.

7. The thermoelectric module according to claim 1, comprising:
a first metal layer provided on a second surface of the substrate;
a second metal layer; and
a second diffusion prevention layer disposed between the first metal layer and the second metal layer, wherein
the second diffusion prevention layer includes a third material having a lower ionization tendency than an ionization tendency of hydrogen.

8. A thermoelectric module comprising:
a substrate;
a first metal layer provided on a second surface of the substrate;
a second metal layer; and
a second diffusion prevention layer disposed between the first metal layer and the second metal layer, wherein
the second diffusion prevention layer includes a third material having a lower ionization tendency than an ionization tendency of hydrogen.

9. The thermoelectric module according to claim 8, wherein
the second diffusion prevention layer has a third contact surface in contact with the first metal layer and a fourth contact surface in contact with the second metal layer, and
each of the third contact surface and the fourth contact surface is formed of the third material.

10. The thermoelectric module according to claim 9, wherein
the second diffusion prevention layer includes a fourth material layer formed of a fourth material having a higher ionization tendency than an ionization tendency of hydrogen, and a third material layer formed of the third material and disposed between the fourth material layer and the second metal layer.

11. The thermoelectric module according to claim 10, wherein
the third material layer is in contact with the second metal layer, and
the fourth material layer is in contact with the first metal layer.

12. The thermoelectric module according to claim 10, wherein the fourth material includes nickel.

13. The thermoelectric module according to claim 8, wherein the third material includes at least one of palladium, platinum, gold, and rhodium.

14. An optical module comprising:
the thermoelectric module according to claim 8; and
a light-emitting element whose temperature is adjusted by the thermoelectric module.

15. The thermoelectric module according to claim 7, wherein
the second diffusion prevention layer has a third contact surface in contact with the first metal layer and a fourth contact surface in contact with the second metal layer, and
each of the third contact surface and the fourth contact surface is formed of the third material.

16. The thermoelectric module according to claim 15, wherein the second diffusion prevention layer includes a fourth material layer formed of a fourth material having a higher ionization tendency than an ionization tendency of hydrogen, and a third material layer formed of the third material and disposed between the fourth material layer and the second metal layer.

17. The thermoelectric module according to claim 16, wherein the third material layer is in contact with the second metal layer, and the fourth material layer is in contact with the first metal layer.

18. The thermoelectric module according to claim 16, wherein the fourth material includes nickel.

19. The thermoelectric module according to claim 7, wherein the third material includes at least one of palladium, platinum, gold, and rhodium.

20. An optical module comprising:
the thermoelectric module according to claim 1; and
a light-emitting element whose temperature is adjusted by the thermoelectric module.
